(19) United States
(12) Patent Application Publication
(10) Pub. No.: US 2012/0288121 A1
(43) Pub. Date: Nov. 15, 2012

(54) ACOUSTIC CONTROL DEVICE

(75) Inventors: Machiko MATSUI, Kobe-shi (JP); Nobutaka MIYAUCHI, Kobe-shi (JP); Masanobu MAEDA, Kobe-shi (JP); Masahiko KUBO, Kobe-shi (JP); Nahoko KAWAMURA, Kobe-shi (JP); Fumitake NAKAMURA, Kobe-shi (JP); Hideto SAITOH, Kobe-shi (JP); Hiroyuki KUBOTA, Kobe-shi (JP); Masayuki TAKAOKA, Kobe-shi (JP); Masanobu WASHIO, Kobe-shi (JP); Yutaka NISHIOKA, Kobe-shi (JP); Osamu YASUTAKE, Kobe-shi (JP)

(73) Assignee: FUJITSU TEN LIMITED, KOBE-SHI (JP)

(21) Appl. No.: 13/467,605

(22) Filed: May 9, 2012

(30) Foreign Application Priority Data
May 13, 2011 (JP) 2011-108742

(51) Int. Cl. H03G 3/20

(52) U.S. Cl. 381/107

(57) ABSTRACT

A DSP performs a sound volume adjustment processing that adjusts a playback sound volume in accordance with a signal level of acoustic data in acoustic contents. Further, when the DSP detects that the acoustic data is switched, the DSP initializes the adjustment to perform a reset processing that performs adjustment in accordance with the acoustic data which is a new playback target. When the changing instruction of the playback position of the acoustic data is accepted, an audio microcomputer instructs the DSP to perform the reset processing.

### CROSS-REFERENCE TO RELATED APPLICATION

This application is based upon and claims the benefit of priority of the prior Japanese Patent Application No. 2011-108742, filed on May 13, 2011, the entire contents of which are incorporated herein by reference.

### BACKGROUND OF THE INVENTION

1. Field of the Invention

The present invention relates to an acoustic control device.

2. Description of the Related Art

In the related art, for example, like a car audio system, acoustic equipment that is capable of playing a plurality of acoustic sources input from a radio tuner or a CD (compact disc) player, and an AUX (auxiliary) which is an external input terminal is known.

In the case of the above-described acoustic equipment, when an acoustic source is switched, the sound volume may be varied due to the difference of the characteristics of the acoustic source (for example, a recording signal level (recording dynamic range) or playback broadband, and kinds of analog/digital signals).

Therefore, recently, an acoustic apparatus that automatically adjusts the sound volume when the acoustic source is switched is suggested. For example, Japanese Patent Application Laid-Open No. 2001-359184 discloses an acoustic apparatus that when a switching signal of an acoustic source is received, constantly maintains the sound volume before and after switching by adjusting a sound volume after switching based on a sound volume before switching.

However, in recent years, for example, there are lots of chances that play data of a compressed sound source recorded in the storage device through the acoustic apparatus by coupling a storage device such as a portable music player to an acoustic apparatus.

In many cases, in the storage device, compressed sound sources that are recorded at various recording signal levels are mixed to be recorded. As a result, when the acoustic contents are switched (for example, transits to the next song), the playing sound volume may be varied due to the difference in the recording signal levels.

In other words, in the acoustic apparatus, not only when the acoustic source such as a CD and DVD (digital versatile disc) is switched, but also when the acoustic contents included in the same acoustic source is continuously reproduced, the sound volume may be varied.

### SUMMARY OF THE INVENTION

The acoustic control device disclosed in this specification includes a sound volume adjusting unit, a reset unit, and an execution instructing unit.

According to the acoustic control device disclosed in this specification, it is possible to appropriately adjust a sound volume between acoustic contents.

### BRIEF DESCRIPTION OF THE DRAWINGS

A better understanding of the present invention or advantages accompanied thereby will become more fully apparent as the following detailed description is read in light of the accompanying drawings.

FIG. 1 is a timing chart illustrating an acoustic waveform, a target level, and a change in a gain of an amplifier;

FIG. 2 is a diagram illustrating a main configuration of acoustic correction;

FIG. 3 is a block diagram illustrating a configuration of a sound volume correcting unit;

FIG. 4 is a diagram illustrating an example of a table in which a signal level is associated with a correction value;

FIG. 5 is a flowchart illustrating a sound volume correcting process performed by a DSP;

FIG. 6 is a view illustrating the transition of an input acoustic signal;

FIGS. 7A and 7B are views illustrating an outline of a reset function;

FIG. 8 is a block diagram illustrating a configuration of an acoustic control device;

FIG. 9 is a block diagram illustrating a configuration of an audio microcomputer;

FIG. 10 is an explanatory view of a converting process of a notification signal between songs;

FIG. 11 is a diagram illustrating an operation example of a reset instructing process;

FIG. 12 is a block diagram illustrating a configuration of a DSP;

FIG. 13 is a diagram illustrating an operation example of a signal level calculating process;

FIG. 14 is a diagram illustrating an operation example of a gain determining process;

FIGS. 15A and 15B are diagrams illustrating an operation example of a reset process;

FIG. 16 is a view illustrating an example of a setting screen;

FIGS. 17A and 173 are diagrams illustrating an example of contents of an effect level;

FIG. 18 is a diagram illustrating an example of contents of an effect pattern;

FIG. 19 is a flowchart illustrating processing sequences of a reset instructing process that is executed by an audio microcomputer; and

FIG. 20 is a flowchart illustrating processing sequences of a reset processing that is executed by a DSP.

### DETAILED DESCRIPTION OF THE PREFERRED EMBODIMENTS

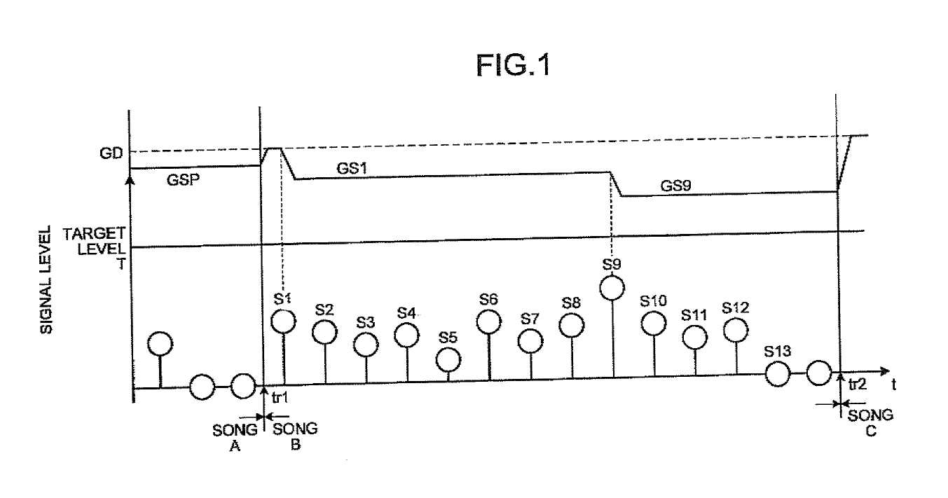

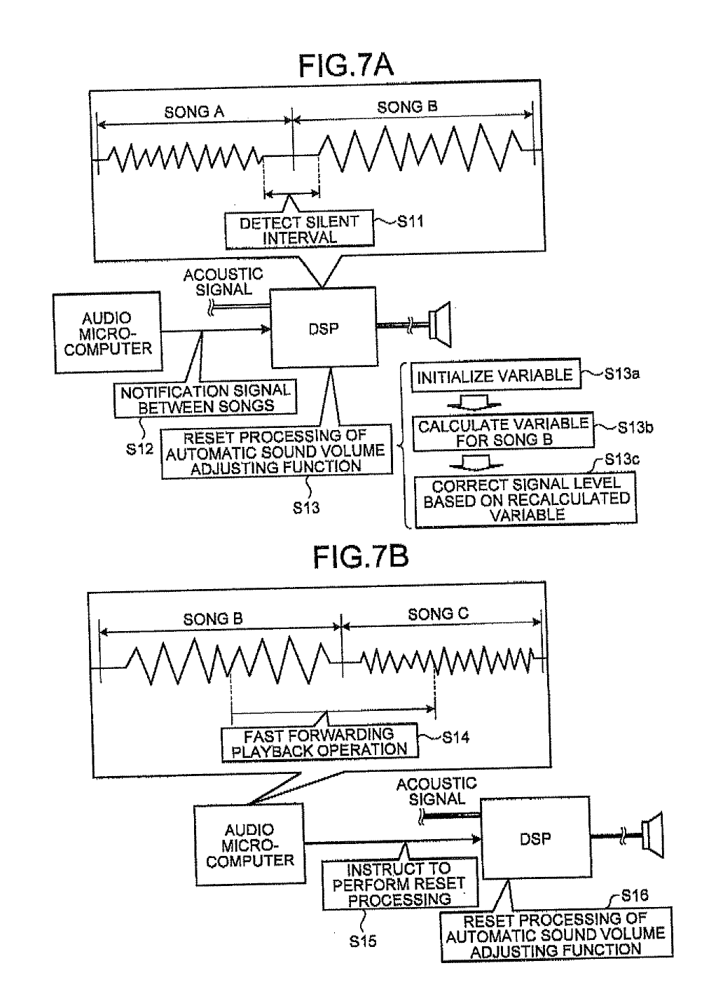

Hereinafter, with reference to the accompanying drawings, a preferred embodiment of a sound volume correcting method according to the present invention will be described in detail. Further, the configuration and the operations of parts that implement basic functions of an example of a sound volume correcting method according to the present invention will be described with reference to FIGS. 1 to 6. Thereafter, regarding the detailed functions, the configuration and the operations thereof will be described with reference to FIG. 7 or later.

### [With Regard to Basic Function]

The sound volume correction of an acoustic signal preferably determines a gain of an amplifier (an attenuance of an attenuator) ideally based on a level distribution of all the songs (basically, the maximum level). However, when the above method is used, it is required to determine a gain by analyzing all the songs before reproducing them. Therefore, a processing load is big and it takes some time to determine the gain so that reproduction is not performed quickly.

A basic sound volume correcting operation according to the present embodiment monitors a value of the signal level and corrects the sound volume while playing the music. For example, an operation that corrects the sound volume based on a moving average value of a signal level value is a basic operation. Further, in this case, a method that determines a correction value by monitoring a head part of the music only for a predetermined period of time and then (while playing the music) uses the correction value is applied. Alternatively, thereafter, if a signal that exceeds the maximum value is detected, a method that performs a process of temporary lowering the sound volume is applied.

Further, there is a technology that corrects the difference of signal levels between the acoustic sources or songs of the same acoustic source so as to maintain the reproduction at the user's preferable sound volume even when the acoustic source or the music is varied. The technology is roughly classified into “application of an acoustic compressor technology” and “a method that uses a psychoacoustic model”.

The “application of an acoustic compressor technology” is a process based on a technology that compresses a dynamic range depending on a signal level, which requires a relatively small amount of processing. However, the dynamic range of the music is small and thus the representation of the original sound quality and intonation is sacrificed. In contrast, “a method that uses a psychoacoustic model” is a technology that analyzes the characteristics of the acoustic signal for every frequency band from an auditory filter model of a human, leads a perceived optimal sound volume balance, and corrects the difference, which allows natural auditory sense. However, the amount of analyzing process of the auditory filter is large, so that a correction dedicated integrated circuit is required, which increases the cost.

The sound volume correcting method according to the present embodiment is made to solve the above problems and realizes a sound volume correction with relatively small amount of processing (or a relatively small size circuit) and suppresses the deterioration of the sound quality.

Therefore, from the above-mentioned objects, basic characteristics on the operation in the sound volume correcting method are as follows. Actual control is performed so as to correspond to the characteristics considering the processing load and the suppression of the reproducing time delay.

First, when a level of an acoustic signal is always corrected while playing one song, in accordance with the change in the correction value, there may be warbling of the sound volume/the lowering of the representation of intonation of music, and change in a tone. Therefore, the correction value is basically constantly maintained throughout the same song (the length of the same song). Second, the correction value is a difference between an average level and a target value of the corresponding song. Third, when a user actually manipulates the volume, based on a fact that a careful manipulation in one song is not performed, a careful correction is not performed but the correction value is lowered only when the input signal is large.

Next, the control contents of the sound volume correcting method will be described by showing an example of a music waveform. A configuration of a main hardware of the sound volume correction is disposed at a stage prior to the volume that is manipulated by the user and controls a gain (an amplification factor or attenuation factor) of an amplifying circuit using the amplifying circuit that serves as an internal volume to perform the sound volume correction. FIG. 1 is a timing chart illustrating a music waveform (represented by an AD conversion value at a predetermined sampling timing) and a target level and a change in a gain of an amplifier.

While playing a song A, the gain of the amplifier is a gain GSP corresponding to a signal level of the song A. Therefore, at a timing tr1 where the song, is changed (for example, when a change is detected in song information (track number) of a music disc and a change is detected in a song for a duration of a silent part and outputting a trigger signal), the gain is changed to an initial gain GD.

Thereafter, the gain is calculated based on a signal level (a signal level at an initial sampling timing) of an initial part (so called a head part of the song) of a newly played song B or an average signal level at a predetermined number of sampling timings (after passing a predetermined period of time, which becomes an average level of the initial part of the song) to control the amplifier. In the present embodiment, a gain GS1 is calculated based on a signal level S1 at the initial sampling timing to control the amplifier.

The signal level is calculated by filtering the acoustic signal using an integral filter (low-pass filter) having an appropriate time constant and then performing a so called moving average process. However, in the present embodiment, a reset processing that accompanies the song change (trigger tr) of the moving average process is not performed.

Since subsequent signal levels S2 to S8 are smaller than the signal level S1, the gain GS1 is maintained. Further, since a next signal level S9 exceeds the signal level S1, a new gain GS9 is calculated and the amplifier is controlled with the gain GS9. Thereafter, since a signal level does not exceed the signal level S9 until the song B finishes, the gain GS9 is maintained until the song finishes. When a next song C is played, the same processings as the song B (it starts from the initialization of a gain, again) begin based on a trigger signal tr2 for changing the song. Even when a power is turned on or the initial song is played, the trigger tr is output and performs the same operation as in the case when the song is changed.

Next, a general operation will be described. An amount of sound volume correction (a gain of an amplifier for correction) is determined in accordance with a signal level of a head part of the song when the song is changed, and then the amount of sound volume correction is updated when the highest signal level in the corresponding song is updated (lowers the gain of the amplifier for correction). Therefore, the amount of the sound volume correction is maintained (the gain of the amplifier for correction is maintained) until the highest signal level in the corresponding song is updated.

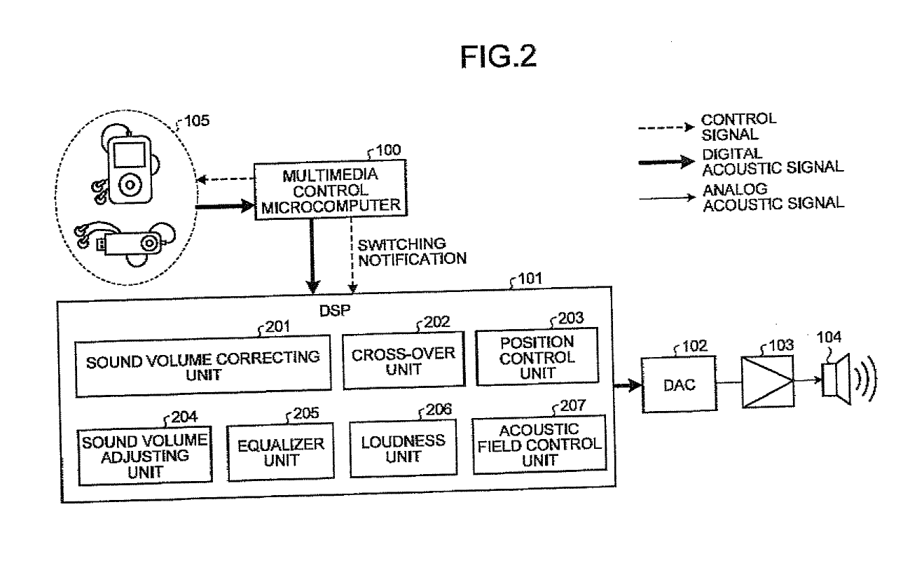

A main configuration of the sound volume correction in the acoustic device according to the present embodiment will be described. An entire image of the acoustic device will be described later. FIG. 2 is a diagram illustrating a main configuration of the sound volume correction. In FIG. 2, the control signal is denoted by a dotted line, a digital acoustic signal is denoted by a heavy line, and an analog acoustic signal is denoted by a fine line.

A multimedia control microcomputer 100 is a microcomputer that controls the operation of the entire acoustic device, includes a CPU (central processing unit), a RAM (random access memory), and a ROM (read only memory) and performs various processings in accordance with programs stored in a memory.

Specifically, in the control for sound volume correction, the multimedia control microcomputer 100 inputs a signal from a portable music player (USB memory audio) 105 and detects the change of the played song based on song number data included in the corresponding signal or sound volume level data (silent interval) determined from sound volume level data), which will be described below. Further, the multimedia control microcomputer 100 outputs acoustic data input from the portable music player (USB memory audio) 105 to a DSP (digital signal processor) 101 without processing the acoustic data.

The DSP 101 is a digital signal processor, that is, a micro computer that is specialized for an arithmetic processing of an acoustic signal, for example, and computes an acoustic signal from the multimedia control microcomputer 100 in response to a set program or parameter (computing coefficient). When the main processing is represented by processing blocks, as shown in FIG. 2, a sound volume correcting unit 201, a cross-over unit 202, a position control unit 203, a sound volume adjusting unit 204, an equalizer unit 205, a loudness unit 206, and an acoustic field control unit 207 are included.

The sound volume correcting unit 201 corrects a sound volume in accordance to a signal level of a song, which will be described in detail below. Further, the cross-over unit 202 adjusts a degree of separation of signals of right and left channels. For example, the cross-over unit 202 mixes the signals of the right and left channels in response to an adjustment operation of the strength of a stereo effect by a user. The position control unit 203, specifically, is installed in a car audio to adjust a level or a phase of a signal each output from the speakers in accordance with a seated status of passengers to control to reproduce the sound so as to be suitable for the seated status.

The sound volume adjusting unit 204 adjusts a level of the acoustic signal in response to the operation of adjusting the sound volume by the user to determine an amplification factor of the amplifier based on the amount of sound volume adjusted by the user regardless of the level of the input acoustic signal (in the DSP 101, a coefficient corresponding to the amount of sound volume adjusted by the user is accumulated to the digital value of the sound). The equalizer unit 205 adjusts a frequency characteristic of the acoustic signal to amplify the signal at respective frequency bands with respective amplification factors in accordance with the amount of the sound volume adjusted by the user.

The loudness unit 206 selectively amplifies signals in a low frequency region and a high frequency region of the acoustic signal with an amplification factor in response to the sound volume adjusting manipulation of the user. The acoustic field control unit 207 performs an adding process of a reverberant sound of the acoustic signal and pseudo-plays the music in an arbitrary space, for example, in a concert hall to realize the pseudo sound field by delaying, amplifying, and adding the acoustic signal.

A DAC 102 is a digital to analog converter that converts the digital acoustic signal processed in the DSP 101 into an analog acoustic signal. The AMP 103 is a power amplifier that amplifies the analog acoustic signal from the DAC 102 to output a sound through a speaker 104 and configured by a transistor.

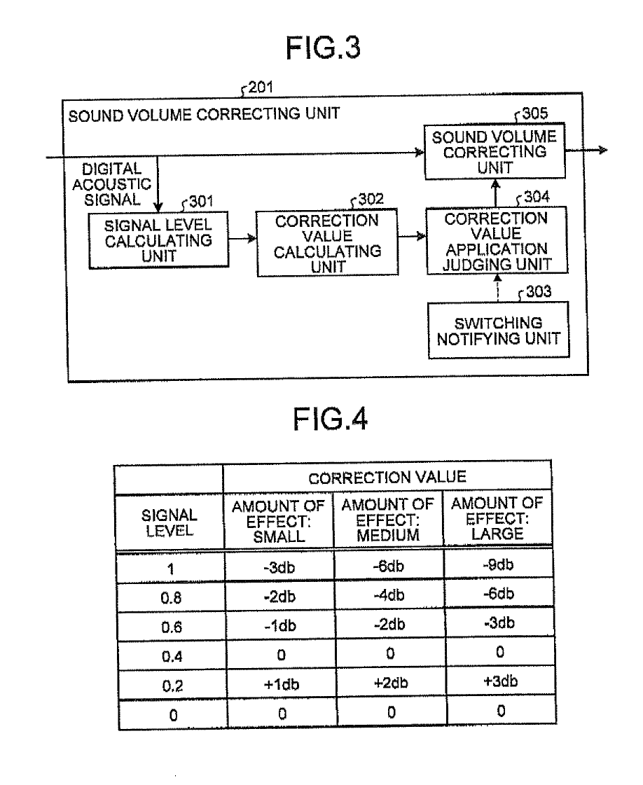

Next, the configuration of the sound volume correcting unit 201 will be described. FIG. 3 is a block diagram illustrating the configuration of the sound volume correcting unit 201 and represents the processings in the DSP 101 as processing blocks.

A signal level calculating unit 301 calculates the signal level of the input acoustic signal. The specific processing is a moving average processing of the input acoustic signal (digital value). In the present embodiment, a moving average processing having different time constants (an averaging period and a weight for each value in the corresponding period are appropriately set) is performed, and a weighting process is performed on the moving average value (amplifies with different gain (different coefficients are accumulated)). Then, a processing that determines the maximum of the processed value as a signal level is performed. Further, if the time constant is set by the manipulation of the user, the sound volume is corrected at the user's preference reaction speed.

A correction value calculating unit 302 calculates a gain that is amplified for a correction value of the acoustic signal, that is, sound volume correction of the acoustic signal. In the present embodiment, the calculation is a calculation method that uses a table. In other words, a table that associates the signal levels with the correction values is stored in a memory and the correction value is selected from the table based on the signal level calculated in the signal level calculating unit 301 and a correction value is calculated to be used for control.

FIG. 4 is a view illustrating an example of the table. The correction value (a gain of an amplifier for correction) is recorded so as to be associated with the signal level. In the present embodiment, the correction value is stared for every correction strength designated by a user (a user designates the degree of the effect of the sound volume correction by manipulating the manipulating unit and in the present embodiment, the strength consists of three stages of large, medium, and small). According to the above configuration, the sound volume correction is performed with the user's preference degree of influence of correction. Further, a method that stores a calculating equation that uses the signal level as a parameter in the memory and applies the signal level that is calculated by the signal level calculating unit 301 to the calculation to calculate the correction value may be applied.

A switching notifying unit 303 performs a correction reset processing based on the change of a song (when the power is on, the switching of a source (sound source) is included). In the present embodiment, the multimedia control microcomputer 100 detects switching of a song, switching of a source, and the power on and outputs the song switching signal (sound volume correcting trigger) to the DSP 101. The switching notifying unit 303 initializes the correction value (changes the correction value to an initial correction value GD) based on the corresponding trigger signal.

The signal level value calculated by the signal level calculating unit 301 is output to the multimedia control microcomputer 100. The multimedia control microcomputer 100 judges the song changing by a silent interval (a period where the signal level value continues to be lower than a level that is considered to be a silence sound) based on the signal level value (for example, it is judged that the song is changed when the silent interval continues for two seconds or longer). In this case, the corresponding trigger signal is also output to the switching notifying unit 303. This processing is specifically effective when a broadcasting (radio or television) that does not have a clear song changing signal is reproduced.

A correction value application judging unit 304 judges whether the correction value is used to correct a sound volume, that is, the acoustic signal is processed with a calculated gain. Therefore, the correction value application judging unit 304 determines the application of the sound volume correction by the manipulation of the correction off by the user or detection of an abnormal correction value due to a noise (input signal level detection value) and performs a reset processing that accompanies the song changing. The sound volume correcting unit 305 is a processing unit that processes the acoustic signal with the calculated gain when the correction value application determining unit 304 determines that the acoustic signal is processed with the calculated gain.

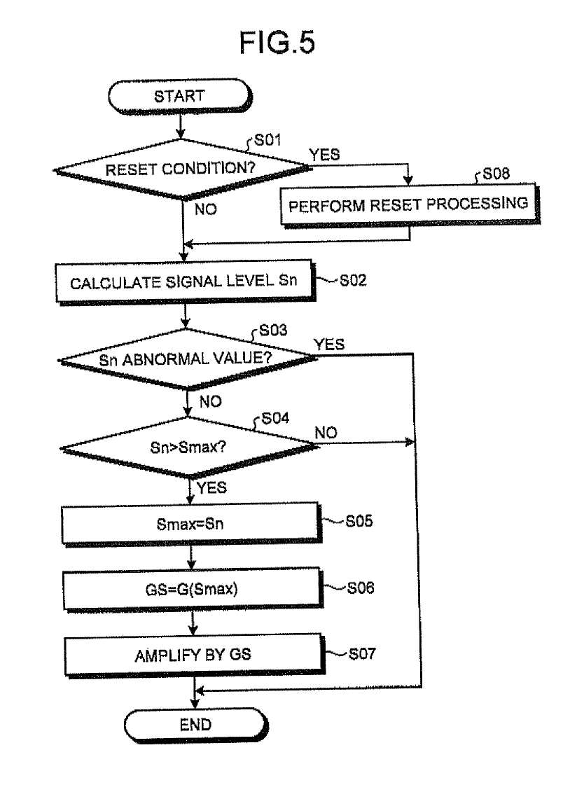

As described above, processing contents of the sound volume correcting unit 201 realized by the processing of the DSP 101 is described with reference to a processing block diagram. However, the processing flows of the DSP 101 will be described with reference to a flowchart. FIG. 5 is a flowchart illustrating a sound volume correcting process performed by the DSP 101.

Further, in the present embodiment, the DSP 101 performs this processing. However, the multimedia control microcomputer 100 and the DSP 101 may share the processing while performing required communication (share the processing so as to perform the suitable processing for them). In addition, this processing is repeated during the sound volume correcting operation (during the reproduction of a sound such as music, when a user sets the sound volume correcting operation to be on).

Step S01 is a processing that determines the reset status. If the reset condition (song switching) is satisfied, the sequence proceeds to step S08. If the reset condition is not satisfied, the sequence proceeds to step S02. Step S08 is a reset processing that initializes the maximum Smax of the signal level (makes zero) or makes the correction value (the amplification factor of the amplifier: gain GS) an initial value (setting value). Further, the gain GS is a value suitable for correction, which is obtained by an experiment. For example, a gain 0 (outputs an input signal as it is) is set. In addition, when the gain GS is a positive value, the signal is amplified. In contrast, when the gain GS is a negative value, the signal is attenuated.

Step S02 is a processing that calculates a signal level Sn from an input acoustic signal and then moves to step S03. The processing according to the present embodiment performs a moving average processing using two kinds of filters having different time constants. Step S02 is a filtering process that selects a higher signal level in the processing result to be a signal level Sn. Further, after the filtering process, an appropriate weighting process (accumulation of weight coefficient) is performed on the respective filtered signals. The processing is to appropriately correct the sound volume of both music whose sound volume is rapidly changed and music whose sound volume is mildly changed. Therefore, the weight coefficient may be set to be an appropriate value based on the experiment so as to appropriately correct the sound volume.

Step S03 determines an abnormality of the calculated signal level Sn. If the signal level is abnormal, the processing is completed. If the signal level is normal, the sequence proceeds to step S04. For example, if the signal level Sn is abnormally high, it is determined to be abnormal and the processing is completed.

Step S04 determines whether a calculated signal level Sn is higher than the maximum signal level Smax in a stored track. If the signal level Sn is higher than the maximum signal level Smax in the track, the sequence proceeds to step S05. If the signal level Sn is not higher than the maximum signal level, the processing is completed. Step S05 updates the maximum signal level Smax to a signal level Sn (a signal level exceeding the maximum signal level Smax) and the sequence proceeds to step S06.

Step S06 calculates the amplification factor (gain) of the amplifier based on the updated maximum signal level Smax to set as an amplifier control value and then proceeds to step S07. Step S06 sets and registers the amplification factor (gain) that is calculated by a calculating equation that uses the maximum signal level Smax as a parameter or a table processing that uses the maximum signal level Smax as a selecting key as an amplifier control value.

Further, even though not shown in the flowchart, in step S06, if there is a reset processing (if an initial gain is set when a song is changed), when the signal level is lower than a predetermined level (significantly low level), it is determined to be a fade-in status which frequently appears in an intro part of the song. In addition, the signal level of the song is estimated as an average signal level. That is, the gain becomes a gain value (for example, gain 0) for an average signal level.

Step 7 controls an amplification factor of the amplifier by the control gain GS and completes this processing. Step 7, outputs the registered amplifier control value to the amplifier as a control signal (if necessary, converts the signal into a signal format (for example, analog value) suitable for control).

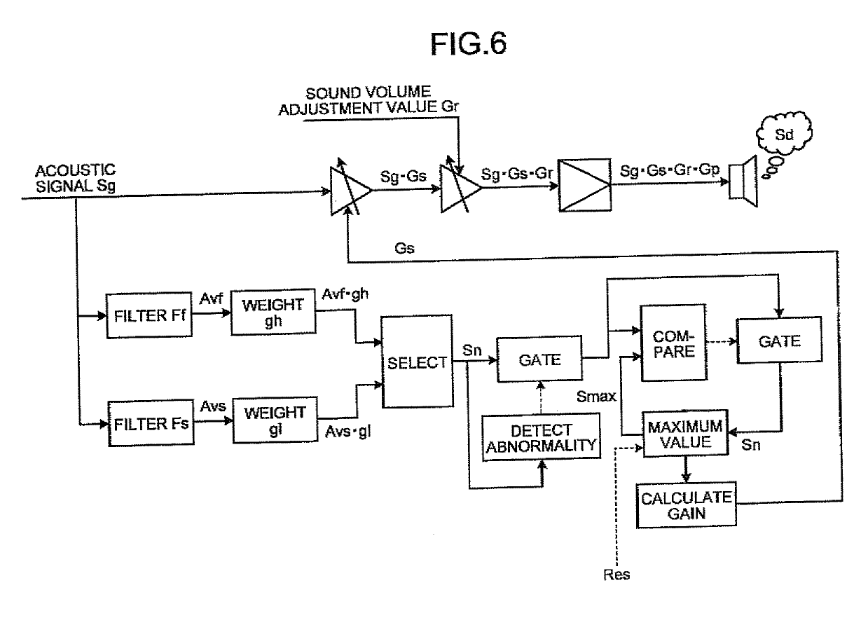

Next, transition of an input acoustic signal by the processing of the DSP 101 described above will be described with reference to FIG. 6 which shows the signal transition.

The input acoustic signal Sg becomes signal level values Avf and Avs by two kinds of moving averaging filters Ff and Fs having different time constants. The signal levels Avf and Ave to which the weighting process is performed and become weight signal level values Avf·gh and Avs·gl. Between the weight signal level values Avf·gh and Avs·gl, a signal level value that is higher than the other is selected to be a signal level Sn for calculating a gain.

When it is determined whether the signal value is an abnormal value, if it is determined to be normal, the signal level Sn for calculating a gain is compared with a stored maximum signal level Smax. As a result of the comparison, if a new signal level Sn for calculating a gain is higher than the past maximum signal level Smax, the stored value of the maximum signal level Smax is updated to the new signal level Sn for calculating a gain. Therefore, a gain Gs for correction amplifier is calculated based on the maximum signal level Smax.

The acoustic signal Sg is amplified based on the gain Gs to be a correction acoustic signal Sg·Gs. Therefore, the correction acoustic signal Sg·Gs whose sound volume is corrected is amplified to an amplification factor Gr of a sound volume adjustment value by a preamplifier based on a user manipulation (Sg·Gs·Gr) and further amplified to a fixed amplification factor Gp by a power amplifier having a fixed amplification factor to be an output acoustic signal Sg·Gs·Gr·Gp to be output through a speaker as an acoustic signal Sd.

Further, if en initializing signal Res is input by switching a song, the maximum signal level Smax is initialized (0) and the gain Gs becomes a gain value based on the maximum signal level Smax at the time of initialization.

As described above, in accordance with the proceeding of reproduction of songs, a maximum signal level is calculated (updated) in the song and the sound volume of the acoustic signal of the song is corrected based on the maximum signal level. Therefore, without previously understanding the signal level of the entire song, the sound volume may be corrected so that the sound volume is quickly corrected. Further, since the sound volume is corrected based on the maximum signal level, relatively simple processing is performed, and the load of the processing device (DSP or CPU) is reduced, which lowers the cost.

### [With Regard to Detailed Function]

In the above-described example of the basic sound volume correcting operation, it is described that the switching of the acoustic contents is detected by the change in song information or the silent interval to perform the reset processing.

However, the sound volume correcting method is not limited thereto, but the reset processing may be performed even in a condition that is difficult to appropriately switch the acoustic contents like the case where the acoustic contents are switched by the changing operation of the playback position such as fast forwarding playback operation, rewind playback operation, or jump operation.

Hereinafter, a reset function in the sound volume correcting method will be described in detail with reference to FIGS. 7A to 7B. First, an outline of the reset function will be described with reference to FIGS. 7A and 7B. FIGS. 7A and 7B are views illustrating the outline of the reset function. FIG. 7A shows an (first) execution timing of the reset processing and FIG. 7B shows an (second) execution timing of the reset processing.

As shown in FIG. 7A, in the reset function, as described above, the DSP (digital signal processor) automatically adjusts the sound volume whenever the acoustic contents which are a playback target are switched. By doing this, for example, even when compressed sound Sources that are recorded at different recoding signal levels are played, it is possible to output a constant sound volume without adjusting the sound volume by a user.

Specifically, in the reset function, when the DSP cannot detect the switching of acoustic contents, an audio microcomputer that controls the DSP issues an instruction of reset processing of the auto sound volume adjusting function to the DSP.

Here, the situation when the DSP cannot detect the switching of the acoustic contents, for example, refers to a situation when the acoustic contents are switched by a playback position designation operation in an arbitrary position such as fast forwarding playback operation, rewind playback operation, or jump operation. Further, the jump operation refers to an operation that moves the playback position in accordance with the amount of operation.

First, it is described that the DSP detects the switching of the acoustic contents to reset the auto sound volume adjusting function.

As shown in FIG. 7A, the DSP detects the silent interval between the acoustic contents first (see step S11 of FIG. 7A). Here, the silent interval indicates an interval where the signal level of the acoustic signal continues at a predetermined level or lower for a predetermined period of time or longer based on acoustic data included in the acoustic contents. Further, hereinafter, in order to distinguish a signal level of the acoustic signal from a level of signal output from the speaker, the former is referred to as a “signal level” and the latter is referred to as “playback sound volume”.

Generally, after a song finishes and before a next song begins, the silent interval is present. The DSP may estimate that the acoustic contents are switched by detecting the silent interval. Further, in FIG. 7A, a silent interval between a song A and a song B is detected.

The DSP judges whether a notification signal between songs is received from an audio microcomputer within a predetermined period of time from the time when the silent interval is detected. Here, the notification signal between songs (corresponds to a song changing trigger signal described above) refers to a signal indicating that the acoustic contents which are a playback target are switched and is set to be output when the audio microcomputer switches the acoustic contents using a program.

If the notification signal between songs is received within a predetermined period of time (see step S12 of FIG. 7A), the DSP resets the automatic sound volume adjusting function (see step S13 of FIG. 7A). Here, the automatic sound volume adjusting function corresponds to the sound volume correcting process described above, and adjusts the signal level of the associated acoustic contents using a variable in accordance with the acoustic data, which is a playback target.

Specifically, the DSP calculates a representative value of the signal level of the acoustic signal (for example, an average value of signal levels at a predetermined time) as a variable based on the acoustic data. The DSP determines a gain based on the calculated representative value and a reference value of the signal level and corrects the signal level using the determined gain (that is, amplifies the acoustic signal using the determined gain). The details of the automatic sound volume adjusting function will be described below.

Further, the reset processing of the automatic sound volume adjusting function, for example, refers to a processing of recalculating a variable corresponding to switched acoustic contents by initializing the variable corresponding to the acoustic contents before being switched.

Specifically, if the reset processing begins, the DSP initializes the variable that has been used so far (see step S13a of FIG. 7A). For example, in the example shown in FIG. 7A, the variable (representative value) calculated based on the acoustic signal of the song A is initialized.

If the variable is initialized, the DSP recalculates the variable. In the example shown in FIG. 7A, since the acoustic data is switched from the song A to the song B, DSP calculates a variable for the song B based on the acoustic signal of the song B (see step S13b of FIG. 7A). As a result, the DSP corrects the signal level based on the variable for the song B that is newly calculated (see step S13c of FIG. 7A).

As described above, the DSP detects the silent interval between the acoustic contents and receives the notification signal between songs from the audio microcomputer to recognize that the acoustic data is switched and perform the reset processing of the automatic sound volume adjusting function. Further, the above sound volume adjustment processing is illustrative but another processing may be performed if a final adjustment value as a result is initialized. For example, the variables are continuously calculated and the reset may make the degree of influence of the variable 0%. In other words, a processing that gradually approaches the degree of influence of the variable to 100% in accordance with the elapsed time from the reset is also available.

When the user changes the playback position of the acoustic contents such as the fast forwarding playback operation, the rewind playback operation, or the jump operation, if the acoustic contents are switched by the user's manipulation, the DSP cannot detect the silent interval. In other words, the DSP does not perform the reset processing, even though the DSP should perform the reset processing of the automatic sound volume adjusting function.

For example, FIG. 7B shows an example that the fast forwarding playback operation is performed during the playback of the song B and the acoustic data that is the playback target is switched into the song C by the operation. In this case, since the DSP cannot perform the reset processing of the automatic sound volume adjusting function, the sound volume of the song C is adjusted using the variable for the song B so that the song C may be played with an inappropriate sound volume.

Therefore, in the resetting function, when the audio microcomputer accepts an instruction of changing the playback position (see step S14 of FIG. 7B), the reset processing is instructed to the DSP (see step S15 of FIG. 73). By doing this even though the DSP cannot detect the switching of the acoustic contents therein, the DSP may perform the reset processing of the automatic sound volume adjusting function at an appropriate timing (see step S16 of FIG. 7B).

As described above, in the acoustic control method, even when the instruction of changing the playback position of the acoustic data is received, the reset processing may be performed. Therefore, the sound volume between the acoustic contents is more appropriately adjusted.

Further, FIGS. 7A and 7B show an example of instructing the DSP so as to perform the reset processing when the DSP performs the sound volume adjustment processing and the reset processing and the audio microcomputer receives the instruction of changing the playback position of the acoustic data. However, the invention is not limited thereto. For example, the processing that receives the instruction of changing the playback position of the acoustic data, a processing of performing the reset processing when the changing instruction is received, and the sound volume adjustment processing may be performed by one processing unit (for example, the DSP, the audio microcomputer, or other controller corresponding thereto).

However, the situation when the reset processing is not started even though the reset processing of the automatic sound volume adjusting function should be performed is not limited to the case when the acoustic contents are switched by the operation of changing the playback position. For example, the setting change related to the sound volume adjusting function may be accepted from the user.

In other words, when the setting change related to the sound volume adjusting function is accepted, the reset processing of the automatic sound volume adjusting function is preferably performed in order to recalculate the variables based on the changed parameter. However, in this case, the silent interval is not detected and the notification signal between songs is not also received. Therefore, the reset processing of the automatic sound volume adjusting function may not be started. That is, even when the user changes the settings, the setting change is not reflected until next acoustic data is switched.

Even when the setting change related to the sound volume adjusting function is accepted, the reset processing may be performed. By doing this, it is possible to immediately reflect the setting change performed by the user.

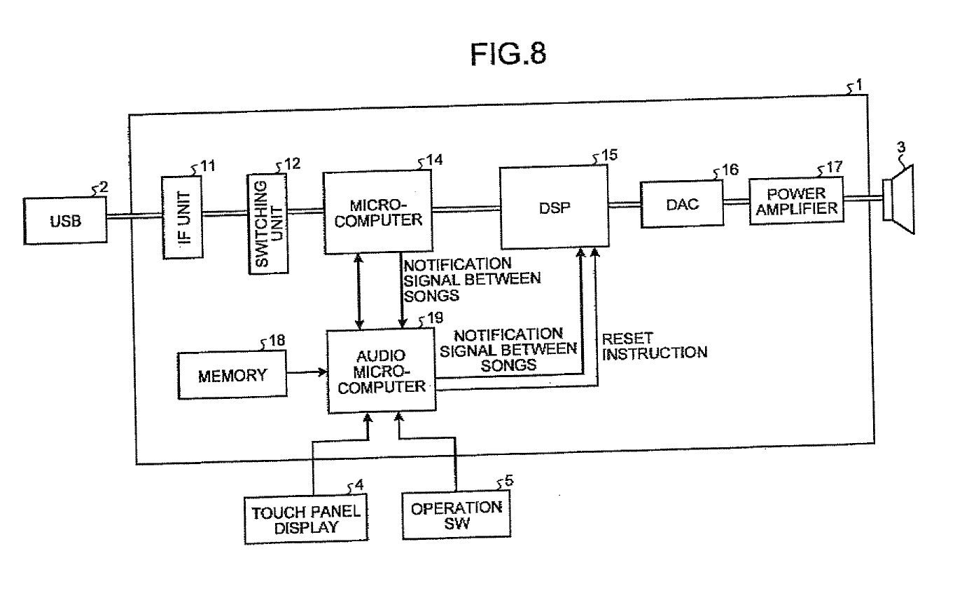

Hereinafter, the resetting function will be specifically described. FIG. 8 is a block diagram illustrating the configuration of the acoustic control device. Hereinafter, as an example of the acoustic control device, a car acoustic control device is described. However, the invention is not limited thereto.

Here, the acoustic control device shown in FIG. 8 is a specific example of the main configuration of the sound volume correction shown in FIG. 2 and includes the basic functions of the example of the sound volume correcting method described referring to FIGS. 1 to 6. Specifically, a DSP 15 shown in FIG. 8 corresponds to the DSP 101 shown in FIG. 2, a microcomputer 14 and an audio microcomputer 19 shown in FIG. 8 correspond to the multimedia control microcomputer 100 shown in FIG. 2. Similarly, a DAC 16, a power amplifier 17, a speaker 3 shown in FIG. 8 correspond to the DAC 102, the AMP 103, and the speaker 104 shown in FIG. 2, respectively.

Further, in FIG. 8, in order to distinguish a line including the acoustic signal and a line of the control signal, the line including the acoustic signal is denoted by double line.

As shown in FIG. 8, the acoustic control device 1 according to the present embodiment includes an IF unit 11, a switching unit 12, and the microcomputer 14. Further, the acoustic control device 1 includes the DSP 15, the DAC (digital analog converter) 16, the power amplifier 17, a memory 18, and the audio microcomputer 19.

In addition, the acoustic control device 1 is connected with a USB (universal serial bus) 2, the speaker 3, a touch panel display 4, and an operation SW (switch) 5. First, the peripheral devices will be described.

The USB 2 is a storage device that records the acoustic data, for example, a portable music player. The acoustic data recorded in the USB 2 is input to the microcomputer 14 through the IF unit 11 and the switching unit 12.

Further, in the USB 2, acoustic contents of compressed sound sources recorded at various recording levels are mixed and recorded. In this case, when the acoustic contents are switched (for example, transits to the next song), the sound volume may be varied due to the difference in the recording levels.

The speaker 3 outputs the acoustic signal output from the acoustic control device 1 as a sound. Further, the acoustic signal output from the acoustic control device 1 is an acoustic signal whose signal level is corrected by the DSP 15 so that a consistently and substantially constant playback sound volume (becomes the substantially constant playback sound volume if the sound volume adjustment values by the user are same, and the constant playback sound volume is changed by the adjustment operation by the user) is output from the speaker 3 in accordance with the sound volume adjustment value by the user, regardless of the recording level of the acoustic contents.

The touch panel display 4 is an input/output device with a touch panel for input attached on a surface of the display for displaying various images. Further, the operation SW 5, for example, is a physical switch provided around the touch panel display 4. The touch panel display 4 and the operation SW 5 output operation information relating to the accepted operation to the audio microcomputer 19 when the operation from the user is accepted.

Examples of the operation that is performed using the touch panel display 4 or the operation SW 5 may include ON/OFF operation of the automatic sound volume adjusting function of the acoustic control device 1 or setting changing operation relating to the automatic sound volume adjusting function.

Next, the respective configurations of the acoustic control device 1 will be described. The IF unit 11 is a communication device that transmits and receives the data to/from the USB 2. If the IF unit 11 receives the acoustic data from the USB 2, the IF unit 11 outputs the received acoustic data to the switching unit 12.

The switching unit 12 is a processing unit that outputs acoustic data of an acoustic source selected from a plurality of acoustic sources by the user to the microcomputer 14. Specifically, if the switching unit 12 receives the switching control signal from the microcomputer 14 in response to the operation of the user for the touch panel display 4 or the operation SW 5, the switching unit 12 switches the acoustic source in accordance with the received switching control signal and outputs the acoustic data from the switched acoustic source to the microcomputer 14.

To the switching unit 12, as the acoustic sources other than the USB 2, an FM·AM radio broadcasting or a CD deck or a DVD deck is connected.

The microcomputer 14 is a processing unit that decodes the acoustic data received from the switching unit 12 and outputs the acoustic signal obtained by the decoding process to the DSP 15.

Further, if the microcomputer 14 detects the switching of the acoustic data based on the acoustic data received from the USB 2 through the IF unit 11 and the switching unit 12, the microcomputer 14 also outputs the notification signal between songs to the audio microcomputer 19.

For example, if the acoustic data recorded in the USB 2 is file format acoustic data, the microcomputer 14 outputs the notification signal between songs to the audio microcomputer 19 at a timing when new file data is obtained from the USB 2. The output processing of the notification signal between songs will be described below.

Further, if the microcomputer 14 receives from the audio microcomputer 19 the operation information such as the fast forwarding playback operation performed by using the touch panel display 14 or the operation SW 5 by the user, the microcomputer 14 also outputs the control information in accordance with the received operation information to the USB 2. The USB 2 outputs the acoustic data in accordance with the control information received from the microcomputer 14.

The DSP 15 has the automatic sound volume adjusting function for constantly maintaining the playback sound volume of the speaker 3 without depending on the acoustic data The DSP 15 is a module that performs a predetermined sound volume adjustment processing on the acoustic signal received from the microcomputer 14 and then outputs the signal to the DAC 16.

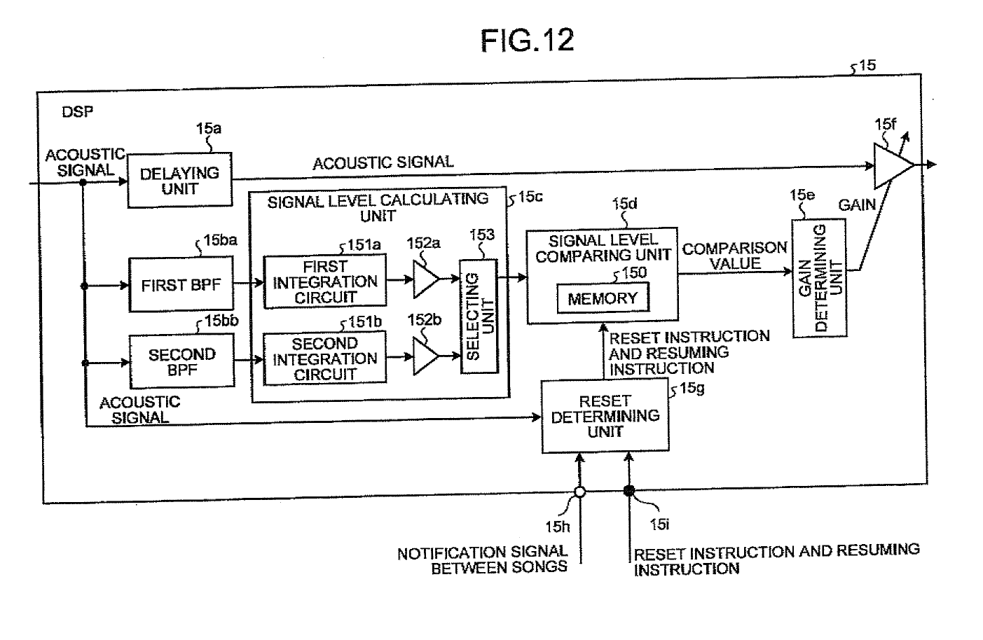

Further, each time the acoustic data is switched, the DSP 15 performs a reset processing of the automatic sound volume adjusting function. In addition, the details of the sound volume adjustment processing and the reset processing performed by the DSP 15 will be described below with reference to FIGS. 12 to 15.

The DAC 16 is a processing unit that converts a digital signal of the acoustic signal received from the DS 15 to which the sound volume adjustment processing is performed into an analog signal. The acoustic signal that is converted into the analog signal by the DAC 16 is output to the power amplifier 17. The power amplifier 17 is a sound (power) amplifier that amplifies the acoustic signal received from the DAC 16 to the speaker 3.

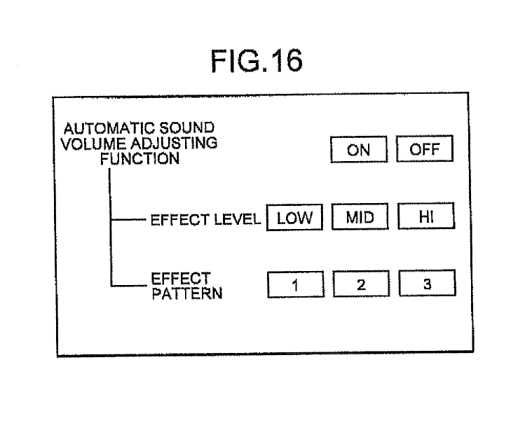

The memory 18 is a storing unit that stores various parameters relating to the automatic sound volume adjusting function. The contents of the parameter stored in the memory 18 will be described below with reference to FIGS. 16 to 18.

The audio microcomputer 19 is a module that controls the DSP 15. For example, when the audio microcomputer 19 receives the notification signal between songs from the microcomputer 14, the audio microcomputer 19 converts the received notification signal between songs into a signal having a format recognizable by the DSP 15 and then outputs the signal to the DSP 15. Further, when the playback position changing operation such as the fast forwarding playback operation of the acoustic data or the setting changing operation for the automatic sound volume adjusting function is performed, the audio, microcomputer 19 outputs the reset instruction of the automatic sound volume adjusting function to the DSP 15.

Further, as another processing, when operation information is received from the touch panel display 4 or the operation SW 5, the audio microcomputer 19 outputs the received operation information to the microcomputer 14.

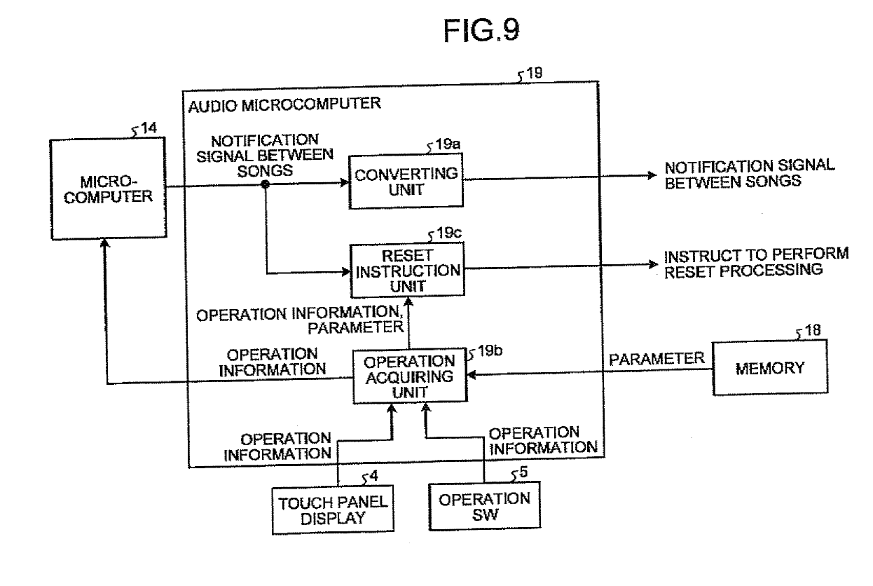

Here, the detailed configuration of the audio microcomputer 19 will be described with reference to FIG. 9. FIG. 9 is a block diagram illustrating the configuration of the audio microcomputer 19. Further, FIG. 9 shows only the components required to describe the characteristics of the audio microcomputer 19 and the description of general components will be omitted.

As shown in FIG. 9, the audio microcomputer 19 includes a converting unit 19a, an operation acquiring unit 19b, and a reset instruction unit 19c.

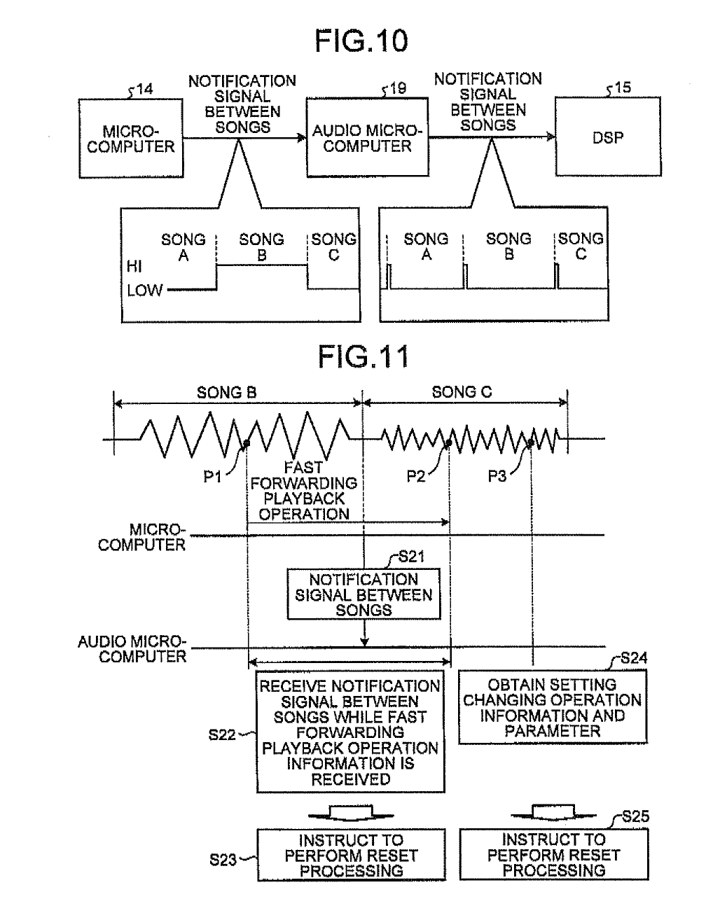

The converting unit 19a is a processing unit that converts the notification signal between songs received from the microcomputer 14 into a signal having a format recognizable by the DSP 15 and outputs the converted notification signal between songs to the DSP 15. Here, the conversion processing of the notification signal between songs performed by the converting unit 19a will be described with reference to FIG. 10. FIG. 10 is an explanatory view of the conversion processing of the notification signal between songs.

As shown in FIG. 10, whenever a new file of the acoustic data is obtained from the USB 2, the microcomputer 14 inverts a port logic of a port for outputting the notification signal between songs to the audio microcomputer 19. For example, as shown in FIG. 10, the microcomputer 14 switches the port logic from Low to Hi at the point of time when a file of the song B is obtained from the USB 2 and switches the port logic from Hi to Low at the point of time when a file of the song C is obtained from the USB 2.

As described above, whenever the acoustic data is switched, the microcomputer 14 outputs an inverting signal to the audio microcomputer 19 as the notification signal between songs. However, the DSP 15 recognizes only whether the signal is received due to the specification of the port. Therefore, using the notification signal between songs having a format that a signal is always output, the DSP 15 cannot recognize that the acoustic data is switched.

Therefore, whenever the port logic of the notification signal between songs input from the microcomputer 14 is inverted, the converting unit 19a of the audio microcomputer 19 outputs one pulse signal to the DSP 15 as the notification signal between songs. By doing this, without changing the specification of the DSP 15, it is possible to allow the DSP 15 to recognize that the acoustic data is switched.

Referring to FIG. 9 again, the audio microcomputer 19 will be continuously described. When the operation information is received from the touch panel display 4 or the operation SW 5, the operation acquiring unit 19b is a processing unit that outputs the received operation information to the microcomputer 14.

Further, when the operation information indicating that the playback position of the fast forwarding playback operation is changed (hereinafter, referred to as “playback position changing operation information”) is received from the touch panel display 4 or the operation SW 5, the operation acquiring unit 19b also outputs the received playback position changing operation information to the reset instruction unit 19c.

Further, when operation information indicating that the setting of the automatic sound volume adjusting function is changed (hereinafter, referred to as “setting changing operation information”) is received from the touch panel display 4 or the operation SW 5, the operation acquiring unit 19b retrieves the parameter corresponding to the received setting changing operation information from the memory 18 and transmits the retrieved parameter to the reset instruction unit 19c together with the setting changing operation information.

The reset instruction unit 190 is a processing unit that instructs the DSP 15 to perform the reset processing of the automatic sound volume adjusting function based on the operation information received from the operation acquiring unit 19b (playback position changing operation information or setting changing operation information) and the notification signal between songs received from the microcomputer 14.

Here, the contents of the reset instruction processing performed by the reset instruction unit 19c will be described with reference to FIG. 11. FIG. 11 is a view illustrating an operation example of the reset instruction processing. FIG. 11 shows an example that as a result of fast forwarding playback operation while playing the song B, the playback position moves from P1 of the song B to P2 of the song C. Further, FIG. 11 also shows an example that the setting changing operation is performed in the playback position P3 of the song C.

Even when the fast forwarding playback operation is performed, the microcomputer 14 may detect that the acoustic data is switched into next acoustic data so as to continuously obtain the acoustic data from the USB 2. For example, if the microcomputer 14 obtains a next acoustic data file from the USB 2 during the fast forwarding playback operation, as shown in FIG. 11, the microcomputer 14 outputs the notification signal between songs to the audio microcomputer 19 (see step S21 of FIG. 11). By doing this, the microcomputer 14 allows the audio microcomputer 19 to recognize that the acoustic data is switched.

Further, in the present embodiment, by outputting the notification signal between songs, the audio microcomputer 19 recognizes that the acoustic data is switched. However, the invention is not limited thereto, and for example, the microcomputer 14 includes a line for connecting with the audio microcomputer 19 in addition to the line for outputting the notification signal between songs. The microcomputer 14 may use the lines to output information indicating that the acoustic data is switched to the audio microcomputer 19.

The reset instruction unit 19c receives the playback position changing operation information from the operation acquiring unit 19b. In this status, when the notification signal between songs is received from the microcomputer 14 (see step S22 of FIG. 11), the reset instruction unit 19c instructs the DSP 15 to perform the reset processing (see step S23 of FIG. 11).

In this case, first, the reset instruction unit 19c outputs the reset instruction to the DSP 15. Further, after outputting the reset instruction, the reset instruction unit 19c outputs the resuming instruction to the DSP 15. Here, the reset instruction refers to a signal that instructs the initialization of the variables used for sound volume adjustment processing. In addition, the resuming instruction refers to a signal that instructs the resumption of the sound volume adjustment processing.

In the meantime, when the setting is changed in the playback position P3 of the song C, if the reset instruction unit 19c receives the setting changing Operation information and the changed parameters from the operation acquiring unit 19b (see step S24 of FIG. 11), the reset instruction unit 19c instructs the DSP 15 to perform the reset processing (see step S25 of FIG. 11).

In this case, the reset instruction unit 19c, first, outputs the reset instruction to the DSP 15. Further, after outputting the reset instruction, the reset instruction unit 19c rewrites the parameter set in the DSP 15 to the changed parameter. After rewriting the parameter, the reset instruction unit 19c outputs the resuming instruction to the DSP 15.

As described above, the reset instruction unit 19c instructs the DSP 15 to perform the reset processing. Therefore, even when the DSP 15 cannot detect that the acoustic contents are switched, the DSP 15 may perform the reset processing of the automatic sound volume adjusting function at an appropriate timing.

Next, the configuration of the DSP 15 will be described with reference to FIG. 12. FIG. 12 is a block diagram illustrating the configuration of the DSP 15.

The configuration of the DSP 15 shown in FIG. 12 is a specific example of the configuration of the sound volume correcting unit 201 shown in FIG. 3, but processing units (the cross-over unit 202, the position control unit 203, the sound volume adjusting unit 204, the equalizer unit 205, the loudness unit 206, and the acoustic field control unit 207) other than the sound volume correcting unit 201 of the DSP 101 shown in FIG. 2 will be omitted.

As shown in FIG. 12, the DSP 15 includes a delaying unit 15a, a first BPF (band pass filter) 15ba, a second BPF 15bb, a signal level calculating unit 15c, a signal level comparing unit 15d, a gain determining unit 15e, and an amplifier 15f. The DSP 15 further includes a reset judging unit 15g, a port 15h, and a port 15i.

Further, the signal level calculating unit 15o includes a first integration circuit 151a, a second integration circuit 151b, amplifiers 152a and 152b, and a selecting unit 153.

The delaying unit 15a is a processing unit that delays the acoustic signal output from the microcomputer 14 for a predetermined period of time and then outputs the signal to the amplifier 15f. That is, the delaying unit 15a delays the acoustic signal so as to match the acoustic signal output from the delaying unit 15a to the output timing of the gain output from the gain determining unit 15e based on the acoustic signal.

The first BPF 15ba and the second BPF 15bb are filters that pass only a predetermined frequency band among the input acoustic signals. Even though, in the present embodiment, two BPFs of the first BPF 15ba and the second BPF 15bb are provided, the DSP 15 may include three or more BPFs.

The first BPF 15ba is a filter that mainly passes the high frequency band. The first BPF 15ba outputs the passed high frequency band acoustic signal to the first integration circuit 151a. Similarly, the second BPF 15bb is a filter that mainly passes the low frequency band. The second BPF 15bb outputs the passed low frequency band acoustic signal to the second integration circuit 151b.

More specifically, the first BPF 15ba passes a signal having a band width between 50 Hz to 20 kHz and does not pass a signal over the above range. In other words, the first BPF 15ba outputs only signals in mostly throughout entire range of human audible bandwidth to the first integration circuit 151a.

Further, the second BPF 15bb passes a signal having a band width between 50 Hz to 300 Hz and does not pass a signal over the above range. In other words, the second BPF 15bb outputs mainly low frequency sound signals to the second integration circuit 151b.

Hereinafter, for the comparison, the signal in the pass band of the first BPF 15ba may be referred to as “high frequency signal” or “high frequency wave” and the acoustic signal in the pass band of the second BPF 15bb may be referred to as “low frequency signal” or “low frequency wave”.

Further, parts of the pass bands of the first BPF 15ba and the second BPF 15bb may overlap. In addition, instead of providing the BPF, the sampling of the acoustic signal may be thinned out. By doing this, the signal processing load may be lowered.

The signal level calculating unit 15c is a circuit block that calculates a representative value of the signal level of the acoustic signal input from the first BPF 15ba and the second BPF 15bb. Further, the representative value is a maximum value of the average values of the signal levels calculated in the respective systems corresponding to the respective BPFs.

The first integration circuit 151a averages the high frequency acoustic signal input from the first BPF 15ba with a short time constant suitable for rapid variation of a signal level and outputs the average value (first average value) to the amplifier 152a. Further, since the signal is averaged by the short time constant, the signal indicates the signal level that quickly follows the signal.

The second integration circuit 151b averages the low frequency acoustic signal input from the second BPF 15bb with a long time constant suitable for slow variation of a signal and outputs the average value (second average value) to the amplifier 152b. Further, since the signal is averaged by the long time constant, the signal indicates the signal level that slowly follows the signal.

Further, the first integration circuit 151a and the second integration circuit 151b include a first amplifier, an adder, a delay device, and a second amplifier. Specifically, the first integration circuit 151a and the second integration circuit 151b amplify the input acoustic signal with a predetermined amplification factor using the first amplifier.

The acoustic signal amplified by the first amplifier is delayed by the delay device for a predetermined period time and then amplified with a predetermined amplification factor (amplification factor <1: attenuated) using the second amplifier. Therefore, the acoustic signals amplified by the second amplifier are added together in the adder and then output.

Here, the first integration circuit 151a and the second integration circuit 151b have different predetermined amplification factors of the second amplifier. That is, the first integration circuit 151a includes a second amplifier having an amplification factor (the amplification factor is reduced and the degree of influence of the past signal becomes smaller) that shortens the time constant as compared with the second integration circuit 151b. In contrast, the second integration circuit 151b includes a second amplifier having an amplification factor (the amplification factor is increased and the degree of influence of the past signal becomes larger) that increases the time constant as compared with the first integration circuit 151a.

In the present embodiment, even though the time constant is simply classified into a short time constant and a long time constant and two integration circuits of the first integration circuit 151a and the second integration circuit 151b are described, the time constant may be classified into three or more time constants and three or more integration circuits corresponding thereto may be provided.

The amplifier 152a multiplies a predetermined weight coefficient corresponding to the first average value to the first average value input from the first integration circuit 151a and then outputs the value to the selecting unit 153. Further, the amplifier 152b multiplies a predetermined weight coefficient corresponding to the second average value to the second average value input from the second integration circuit 151b and then outputs the value to the selecting unit 153.

The weight coefficients that are used by the amplifier 152a and the amplifier 152b are input from the audio microcomputer 19.

Specifically, weight coefficient information which includes the weight coefficient, for example, is information relating to the weight coefficient for correcting the sound volume stored in the memory 18 shown in FIG. 8, and an item of “pattern number”, an item of “type” and an item of “weight coefficient” are associated with each other to be stored therein.

The item of “pattern number” is an item of pattern numbers that are assigned to weight coefficient combined patterns for systems of the integration circuit. The weight coefficient information is a record for every pattern number and the relationship between information may be managed. In this case, the pattern number becomes a main key for searching the records of the weight coefficient information 8a.

The item of “type” is an item storing the types of the sub keys for searching the records. The item of “type” further includes an item of “category”, an item of “tempo”, and an item of “melody”.

For example, the item of “category” is an item of information such as “rock” or “classic” for identifying the category of the music. Further, the item of “tempo” is an item of information such as “fast” or “slow” for identifying the tempo of the music. In addition, the item of “melody” is an item of information such as “hard” or “soft” for identifying the melody of the music. Furthermore, the item of “weight coefficient” is an item of the combination of the weight coefficients for systems of the integration circuit corresponding to the pattern number.

The combination of the weight coefficients may be determined in accordance with the information of the item of “type”. For example, if an acoustic signal which contains lots of high frequency waves and is steep, that is, the category is “rock”, the tempo is “fast”, and the melody is “hard” is input, the weight coefficient K corresponding to the first integration circuit 151a that is “1”, which is relatively high and the weight coefficient L corresponding to the second integration circuit 151b that is “0.9”, which is relatively low may be combined.

In contrast, if an acoustic signal which contains lots of low frequency waves and is mild, that is, the category is “classic”, the tempo is “slow”, and the melody is “soft” is input, like the record of “pattern 2”, the weight coefficient K that is “0.7”, which is relatively low and the weight coefficient L that is “1”, which is relatively high may be combined. Further, the weight coefficient combination pattern may be set so as to be varied by the operation of the user.

The selecting unit 153 is a circuit block that outputs a maximum value between the respectively weighted first average value and second average value as the representative value of the signal level to the signal level comparing unit 15d.

Specifically, the selecting unit 153 includes a comparing unit and a dividing unit. The comparing unit compares the input first average value and second average value using a comparator and outputs the maximum value thereof to the dividing unit. The dividing unit divides the maximum value input from the comparing unit by the weight coefficient of the corresponding amplifier 152a or amplifier 152b to return the value before being weighted and output the value as the representative value. Further, a reciprocal of the weight coefficient may be multiplied. In addition, without having the dividing unit, the maximum value output from the comparing unit may be output as the representative value.

Further, the calculation processing of the representative value of the signal level of the signal level calculating unit 15c is not limited as described above. Hereinafter, another processing example of the signal level calculating unit 15c will be described.

The acoustic signal input from the BPF to the signal level calculating unit 15c is an acoustic signal having a plurality of channels. For example, the acoustic signal includes two channels, a left channel Loh a nd a right channel Rch. The signal level calculating unit 15c selects a signal level having a larger absolute value between the input Lch and Rch signals. The signal level calculating unit 15c calculates the representative value of the signal level of the acoustic signal based on the selected signal level and outputs the calculated representative value to the signal level comparing unit 15d.

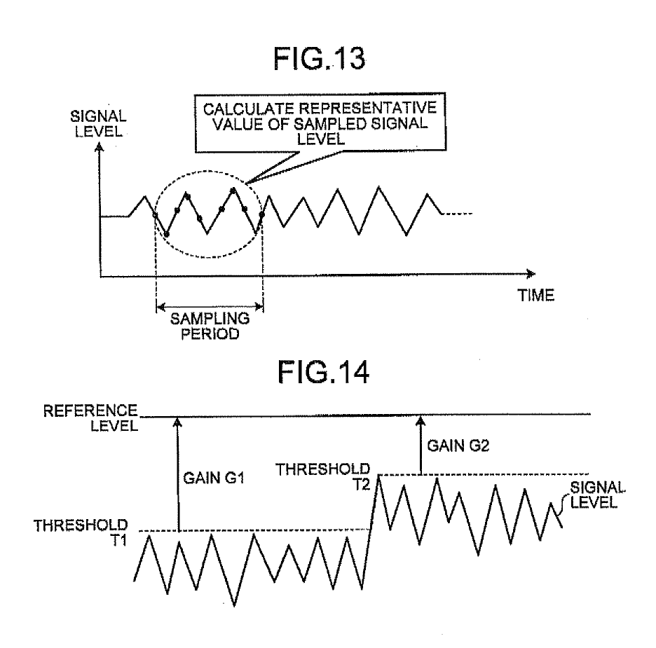

Here, the operation example of calculating the representative value will be described with reference to FIG. 13. FIG. 13 is a view illustrating an operation example of the signal level calculation processing. In FIG. 13, an acoustic signal having a larger absolute value of the signal level between the Lch and Rch acoustic signals input to the signal level calculating unit 15c is shown.

Here, even though the signal level having a larger absolute value is selected between the Lch and Rch signals, the invention is not limited thereto. If one value is derived from the information of the acoustic signal having a plurality of channels, any method may be used. For example, an average value of signal levels of both channels may be calculated.

As shown in FIG. 13, the signal level calculating unit 15c retrieves an acoustic signal in a predetermined sampling period from the input acoustic signals. The signal level calculating unit 15c calculates a representative value of the retrieved acoustic signal. For example, the signal level calculating unit 15c calculates an average value of the signal levels of the retrieved acoustic signals as a representative value. However, the invention is not limited thereto, but the signal level calculating unit 15c may calculate the maximum value of the signal levels of the retrieved acoustic signals as a representative value.

Here, the length of the sampling period shown in FIG. 13 may be changed by the setting changing operation of the user. Three sampling periods having different lengths are stored in the memory 18 as a parameter “effect pattern”.

Referring to FIG. 12 again, the signal level comparing unit 15d will be described. The signal level comparing unit 15d is a processing unit that compares the signal level (representative value) input from the signal level calculating unit 15c with a threshold stored in the memory 150 and outputs a higher value (hereinafter, referred to as “comparison value”) to the gain determining unit 15e.

Specifically, as a result of the comparison, if the signal level (representative value) input from the signal level calculating unit 15c is lower than the threshold, the signal level comparing unit 15d outputs a value of the threshold to the gain determining unit 15e as a comparison value. In contrast, if the signal level (representative value) input from the signal level calculating unit 15c is higher than the threshold, the signal level comparing unit 15d outputs the signal level (representative value) input from the signal level calculating unit 15c to the gain determining unit 15e as a comparison value.

Further, if the signal level (representative value) input from the signal level calculating unit 15c is higher than the threshold, the signal level comparing unit 15d stores the signal level (representative value) output to the gain determining unit 15e as a new threshold in the memory 150.

That is, the signal level comparing unit 15d continuously outputs the value of the threshold as a comparison value until the signal level (representative value) input from the signal level calculating unit 15c exceeds the threshold stored in the memory 150. If the signal level (representative value) that exceeds the threshold is input, the signal level (representative value) is stored in the memory 150 as a new threshold, and the value of the threshold is continuously output as a comparison value until the signal level (representative value) that exceeds the threshold is input. Further, the threshold stored in the memory 150 may be a variable corresponding to acoustic data that is a playback target.

If a reset instruction is received from the reset judging unit 15g, the signal level comparing unit 15d initializes the threshold stored in the memory 150 (for example, makes zero) and temporally stops the signal level comparison processing (processing that outputs the comparison value). If the resuming instruction is received from the reset judging unit 15g, the signal level comparing unit 15d resumes the signal level comparison processing, which will be described below.

The gain determining unit 15e is a processing unit that determines a gain of the acoustic signal based on the comparison value input from the signal level comparing unit 15d and a predetermined reference value. Here, the gain determination processing performed by the gain determining unit 15e will be described with reference to FIG. 14. FIG. 14 is a view illustrating an operation example of the gain determination processing. Further, in FIG. 14, the operation example of the signal level comparing unit 15d will be also described.

As shown in FIG. 14, the signal level comparing unit 15d outputs a threshold T1 to the gain determining unit 15e as a comparison value until the signal level (representative value) input from the signal level calculating unit 15c exceeds the threshold T1 stored in the memory 150.

The gain determining unit 15e determines a gain G1 that matches the input threshold T1 to the reference value. The gain G1 may be calculated by dividing the reference value by the threshold T1 or determined using a table that defines the relationship between the comparison value and the gain in advance.

In the meantime, if the signal level (representative value) input from the signal level calculating unit 15c exceeds the threshold T1 stored in the memory 150, the signal level comparing unit 15d stores the signal level (representative value) in the memory 150 as a new threshold T2. Further, the signal level comparing unit 15d outputs the threshold T2 to the gain determining unit 15e as a comparison value.

As a result, the gain determining unit 15e newly determines a gain G2 that matches the input threshold T2 to the reference value.

Further, here, an example that the gain determining unit 15e determines a coefficient that matches the comparison value to the reference value as a gain is described. However, a user may change a degree that the comparison value approaches the reference value by the setting changing operation. Three coefficients indicating the degree that the comparison value approaches the reference value are stored in the memory 150 as a parameter “effect level”.

Referring to FIG. 12 again, the reset judging unit 15g will be described. The reset judging unit 15g is a processing unit that judges whether the reset processing of the automatic sound volume adjustment processing is performed. Further, if it is judged that the reset processing is performed, the reset judging unit 15g outputs the reset instruction to the signal level comparing unit 15d and also outputs the resuming instruction.

For example, the reset judging unit 15g judges whether the reset processing is performed based on the acoustic signal input from the microcomputer 14 and the notification signal between songs input from the audio microcomputer 19 through the port 15h. Further, the reset judging unit 15g outputs the reset instruction and the resuming instruction to the signal level comparing unit 15d in accordance with the reset instruction and the resuming instruction input from the audio microcomputer 19 through the port 15i. In addition, the port 15i, for example, is an I2C port and the port 15h is a JX port.

The amplifier 15f is a processing unit that amplifies the acoustic signal output from the delay processing unit 15a in accordance with a gain output from the gain determining unit 15e. That is, the amplifier 15f corrects the signal level of the acoustic signal output from the delay processing unit 15a using a gain output from the gain determining unit 15e. The acoustic signal whose signal level is corrected by the amplifier 15f is output to the DAC 16.

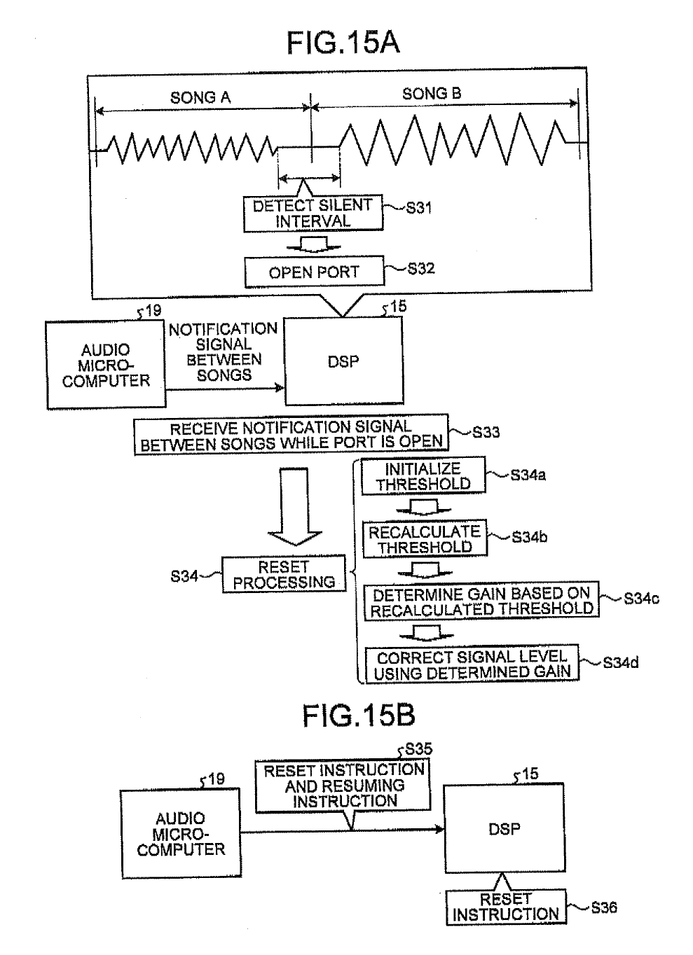

Here, the reset processing performed by the DSP 15 will be described with reference to FIGS. 15A and 15B. FIGS. 15A and 15B are views illustrating operation examples of the reset processing. Further, FIG. 15A shows an (first) execution timing of the reset processing and FIG. 158 shows an (second) execution timing of the reset processing.

As shown in FIG. 15A, the reset judging unit 15g of the DSP 15, first, detects a silent interval of the acoustic signal input from the microcomputer 14 (see step S31 of FIG. 15A). The silent interval refers to an interval where the signal level of the acoustic signal continuously is maintained at a predetermined level or lower for a predetermined period of time or longer. In FIG. 15A, a silent interval between the song A and the song B is detected.

Further, the reset judging unit 15g, for example, may calculate the signal level of the acoustic signal input from the microcomputer 14 and detect the silent interval using the calculated signal level. The signal level (representative value) calculated by the signal level calculating unit 15c may be obtained to detect the silent interval using the obtained signal level (representative value).

Further, if the silent interval is detected, the reset judging unit 15g opens the port 15h (see step S32 of FIG. 15A). While the port 15h is open, if the notification signal between songs is received from the audio microcomputer 19 (see step S33 of FIG. 15A), the reset judging unit 15g judges that the reset processing is performed. By doing this, in the DSP 15, the reset processing of the automatic sound volume adjusting function is started (see step S34 of FIG. 15A).

Specifically, in the DSP 15, the reset judging unit 15g outputs the reset instruction to the signal level comparing unit 15d and the signal level comparing unit 15d that receives the reset instruction initializes the threshold stored in the memory 150 (see step S34a of FIG. 15A). In this case, the signal level comparing unit 15d temporally stops the signal level comparison processing.

Continuously, in the DSP 15, the reset judging unit 15g outputs the resuming instruction to the signal level comparing unit 15d and the signal level comparing unit 15d that receives the resuming instruction resumes the signal level comparison processing.

As a result, the signal level comparing unit 15d compares the representative value of the signal level of the acoustic signal with an initial value of the threshold (for example, 0) based on the acoustic data (here, the song B) which becomes a new playback target) (see step S34b of FIG. 15A). In this case, since the representative value of the signal level is higher than the initial value of the threshold, the representative value (that is, a representative value of the signal level of the acoustic signal based on the song B) is stored in the memory 150 as a new threshold.

Continuously, in the DSP 15, the signal level comparing unit 15d outputs the threshold newly stored in the memory 150 (that is, the threshold corresponding to the song B) to the gain determining unit 15e as a comparison value and the gain determining unit 15e determines a gain corresponding to the song B based on the comparison value and the reference value (see step S34c of FIG. 15A).

In the DSP 15, the amplifier 15f corrects the signal level of the acoustic signal using a gain determined by the gain determining unit 15e (see step 34d of FIG. 15A).

That is, as long as the signal level does not exceed the threshold, the gain is not changed. Therefore, it is possible to prevent the discomfort in the sound to the user due to the frequent changes in the gain. In the meantime, if the signal level exceeds the threshold, since the gain may be lowered, the saturation of the acoustic signal when the change in the signal level of the acoustic signal is large may be prevented and thus it is possible to provide a comfortable sound to the user. Therefore, the user does not need to manually adjust the sound volume for the changes in the signal level of the acoustic signal caused by the difference in recording levels.

As described above, the DSP 15 detects the silent interval between the acoustic data and receives the notification signal between songs from the audio microcomputer 19 to recognize that the acoustic contents are changed and perform the reset processing of the automatic sound volume adjusting function.

In the meantime, as shown in FIG. 15B, if the reset judging unit 15g receives the reset instruction and the resuming instruction from the audio microcomputer 19 (see step S35 of FIG. 15B), the reset judging unit 15g performs the reset instruction and the resuming instruction for the signal level comparing unit 15d in accordance with the reset instruction and the resuming instruction. As a result, in the DSP 15, the reset processing same as the reset processing shown in step S34 of FIG. 15A is performed (see step S36 of FIG. 15B).

That is, if the reset processing is performed only at an execution timing shown in FIG. 15A, for example, if it is switched to the next acoustic contents by the fast forwarding playback operation, the silent interval may not be detected. Further, even though the reset processing should be performed, the reset processing is not performed. This is the same in the case when the setting change operation is accepted.

Therefore, in the acoustic control device 1, the audio microcomputer 19 detects that the acoustic contents are switched by the fast forwarding playback operation or the setting changing operation is performed and instructs the DSP 15 to perform the reset processing. By doing this, even though the DSP 15 cannot detect that the acoustic contents are switched, the DSP 15 can perform the reset processing of the automatic sound volume adjusting function at an appropriate timing.

However, in the acoustic control device 1, the setting change of the automatic sound volume adjusting function is available, which will be described below. FIG. 16 is a view illustrating an example of the setting screen. As shown in FIG. 16, the user may turn on/off the automatic sound volume adjusting function and change the settings such as the effect level or the effect pattern using an input operation to the touch panel display 4 or the operation SW 5.

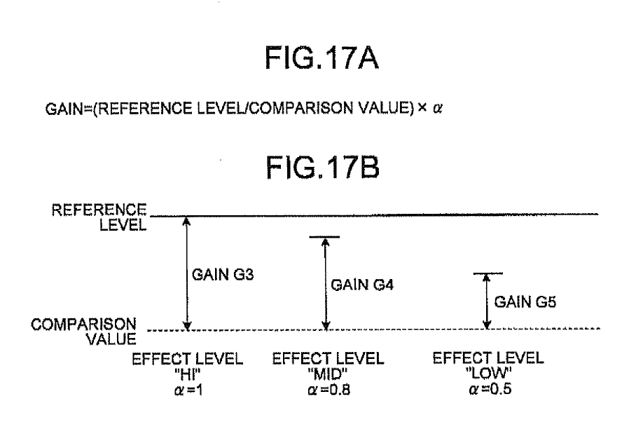

The “effect level” refers the degree that the gain determining unit 15e approaches the comparison value input from the signal level comparing unit 15d to the reference value. Here, the contents of the effect level will be described with reference to FIGS. 17A and 17B. FIGS. 17A and 173 are views illustrating an example of the contents of the effect level. FIG. 17A shows an equation used to determine a gain and FIG. 17B shows the relationship between the effect level and the gain.

As shown in FIG. 17A, the gain determining unit 15e determines the gain using an equation of gain=(reference level/comparison value)×α. That is, the gain determining unit 15e determines a value obtained by multiplying a coefficient that matches the comparison value output from the signal level comparing unit 15d to the reference level by a predetermined parameter value “α” as a gain. Therefore, the parameter value “α” is determined in accordance with the effect level set by the user.

For example, as shown in FIG. 17B, when the effect level during the setting is “Hi”, the gain determining unit 15e calculates the gain G3 using α=1. As a result, the coefficient that matches the comparison value output from the signal level comparing unit 15d to the reference Level is determined as the gain. Further, in the example shown in FIG. 14, the effect level is set to “Hi”.

Further, when the effect level during the setting is “Mid”, the gain determining unit 15e calculates the gain G4 using α=0.8. In addition, the effect level during the setting is “Low”, the gain G5 is calculated using α=0.5. As described above, by changing the effect level, the degree that the comparison value approaches the reference value may be varied.

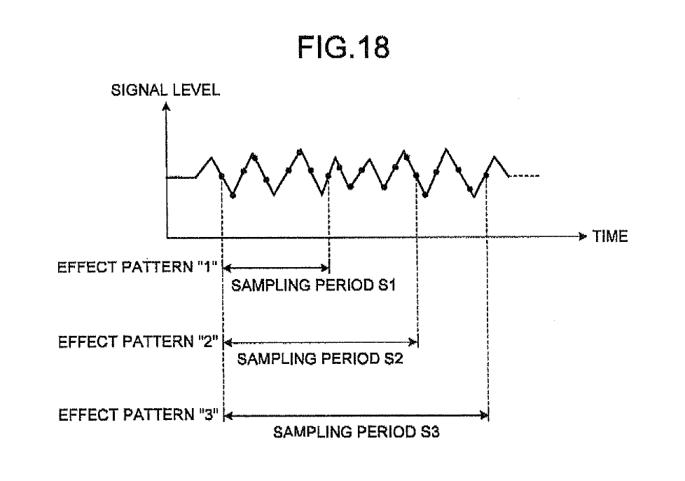

Referring to FIG. 16 again, the “effect pattern” refers to a follow-up speed of the sound volume adjustment processing for the change in the acoustic signal. Here, the contents of the effect pattern will be described with reference to FIG. 18. FIG. 18 shows an example of the contents of the effect pattern.

As shown in FIG. 18, when the effect pattern during the setting is “1”, the signal level calculating unit 15c calculates the representative value of the signal level using a shortest sampling period S1. Further, when the effect pattern during the setting is “2”, the signal level calculating unit 15c calculates the representative value of the signal level using a sampling period S2 which is longer than the sampling period S1. In addition, when the effect pattern during the setting is “3”, the signal level calculating unit 15c calculates the representative value of the signal level using a sampling period S3 which is longer than the sampling period S2.

Here, as the length of the sampling period is set to be longer, a signal level (representative value) that slowly (at a low speed) follows the change in the acoustic signal is output. Further, as the length of the sampling period is set to be shorter, a signal level (representative value) that quickly (at a high speed) follows the change in the acoustic signal is output.

That is, by changing the setting of the length of the sampling period, the sensitivity of the sound volume adjustment processing with respect to the change in the signal level of the acoustic signal may be changed. For example, if the sound volume from the speaker 3 is constantly maintained as long as possible, the user may set the effect pattern “1” so as to calculate the representative value of the signal level during the short sampling period S1. By doing this, the sound volume adjustment processing sensitively follows the change in the acoustic signal so as to further suppress the change in the sound volume.

Further, the DSP 15 includes a storing unit (not shown) that stores a parameter such as the effect level or the effect pattern. The gain determining unit 15e or the signal level calculating unit 15o retrieves required parameters from the storing unit to perform the processing. In addition, when the audio microcomputer 19 accepts the setting changing operation of the effect level or the effect pattern, the audio microcomputer 19 rewrites the parameter stored in the storing unit of the DSP 15 to the changed parameter.

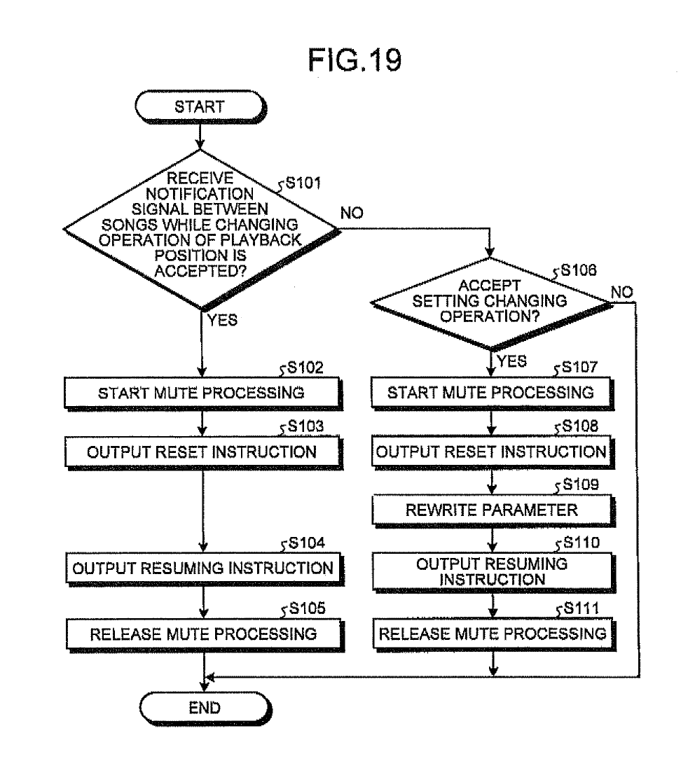

Next, specific operations of the audio microcomputer 19 and the DSP 15 will be described. First, the specific operation of the audio microcomputer 19 will be described with reference to FIG. 19. FIG. 19 is a flowchart illustrating processing sequences of the reset instruction processing performed by the audio microcomputer 19. Further, this processing is repeated during the playback operation.

As shown in FIG. 19, the audio microcomputer 19 judges whether the notification signal between songs is received while the changing operation of the playback position (for example, the fast forwarding playback operation) is accepted (step S101). In this processing, if the audio microcomputer 19 judges that the notification signal between songs is received while the changing operation of the playback position is accepted (step S101, Yes), the audio microcomputer 19 starts a mute processing that makes the signal level of the acoustic signal output from the DSP 15 zero (step S102).

Next, the audio microcomputer 19 outputs the reset instruction to the DSP 15 (step S103), outputs the resuming instruction (step S104), and then releases the mute processing (step S105). Thereafter, the processing is completed.

In the meantime, if the audio microcomputer 19 judges that the notification signal between songs is not received while the fast forwarding playback operation is accepted (step S101, No), the audio microcomputer 19 judges whether the setting changing operation is accepted (step S106). If the audio microcomputer 19 judges that the setting changing operation is accepted (step S106, Yes), the audio microcomputer 19 starts the mute processing (step S107) and then outputs the reset instruction to the DSP 15 (step S108).

Further, the audio microcomputer 19 rewrites a parameter (effect level or effect pattern) relating to the sound volume adjustment processing of the DSP 15 in accordance with the accepted setting changing operation (step S109). Thereafter, the audio microcomputer 19 outputs the resuming instruction (step S110) and then releases the mute processing (step S111). When the processing of step 111 is completed, or the setting changing operation is not accepted in step S106 (step S106, No), the audio microcomputer 19 completes the processing. In addition, since the processing is repeatedly performed, as a result, the DSP 15 performs the processing from step S101 again.

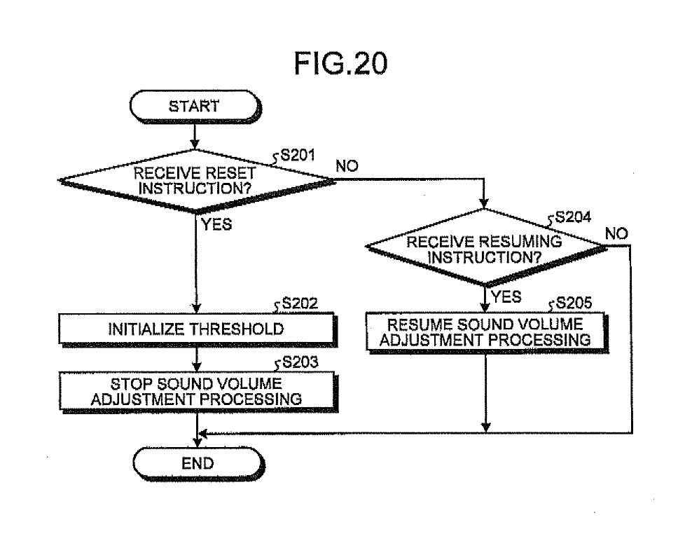

Next, the specific operation of the DSP 15 will be described with reference to FIG. 20, FIG. 20 is a flowchart illustrating processing sequences of the reset processing performed by the DSP 15. FIG. 20 shows the processing sequences when the reset processing is performed according to the reset instruction and the resuming instruction received from the audio microcomputer 19. Further, the processings by the flowchart shown in FIG. 10 are repeatedly performed during the playback operation.

As shown in FIG. 20, the DSP 15 judges whether the reset instruction is received from the audio microcomputer 19 (step S201). If the DSP 15 judges that the reset instruction is received from the audio microcomputer 19 (step S201, Yes), the DSP 15 initializes the threshold stored in the memory 105 (step S202) and then temporally stops the sound volume adjustment processing (step S203) and completes the processing. Further, the DSP 15 may temporally stops the sound volume adjustment processing by, for example, stopping the signal level comparison processing of the signal level comparing unit 15d.

In the meantime, when the reset instruction is not received from the audio microcomputer 19 (step S201, No), the DSP 15 judges whether the resuming instruction is received from the audio microcomputer 19 (step S204). When the DSP 15 judges that the resuming instruction is received from the audio microcomputer 19 (step S204, Yes), the DSP 15 resumes the sound volume adjustment processing (step S205). By doing this a threshold corresponding to acoustic data which is a new playback target is calculated and the signal level of the acoustic data which is a new playback target is corrected using the calculated threshold.

When the processing of step S205 is completed, or the resuming instruction is not received in step S204 (step S204, No), the DSP 15 completes the processing. Further, since the processing is repeatedly performed, as a result, the DSP 15 performs the processing from step S201 again.

As described above, in the present embodiment, the DSP 15 adjusts the signal level of the acoustic data using the threshold in accordance with the acoustic data which is the playback target. Further, in the present embodiment, when the DSP 15 detects the silent interval between the acoustic data, the DSP 15 initializes the threshold to perform the reset processing that calculates the variable in accordance with the acoustic data which is a new playback target for the sound volume adjustment processing. In addition, in the present embodiment, the audio microcomputer 19 accepts the fast forwarding playback operation of the acoustic data, the audio microcomputer 19 instructs the DSP 15 to perform the reset processing. Therefore, it is possible to appropriately adjust the sound volume between acoustic contents.

Further, in the present embodiment, an example of the reset processing relating to the fast forwarding playback is mainly described. Even when the reset processing is performed on an operation that is difficult to appropriately switch the acoustic contents such as the rewind playback and an operation that the user designates the playback position, the same effect may be obtained.

Even though the present embodiments of the acoustic control device according to the present invention have been described in detail with reference to the drawings, these are illustrative. It is further understood that the invention may be embodied as various changes and modifications based on the knowledge of those skilled in the art.

As described above, the acoustic control device according to the present invention is effective when the sound volume is appropriately adjusted between the acoustic contents, and specifically, applied to a car acoustic control device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An acoustic control device, comprising:
a sound volume adjusting unit that performs a sound volume adjustment processing that adjusts a playback sound volume in accordance with a signal level of acoustic data in acoustic contents;
a reset unit that performs a reset processing adjusting in accordance with the acoustic data which is a new playback target for the sound volume adjusting unit by initializing the adjustment when it is detected that the acoustic data is switched; and
an execution instructing unit that instructs the reset unit to perform the reset processing when the changing instruction of a playback position of the acoustic data is accepted.

2. The acoustic control device according to claim 1, wherein when the acoustic contents which are the playback target are switched by the changing instruction of the playback position, the execution instructing unit instructs the reset unit to perform the reset processing.

3. The acoustic control device according to claim 1, wherein when the setting changing operation relating to the sound volume adjustment processing is accepted, the execution instructing unit performs a processing that instructs the reset unit to perform the reset processing and a processing that changes a parameter of the sound volume adjusting unit in accordance with the accepted setting changing operation.

4. The acoustic control device according to claim 1, wherein the sound volume adjusting unit includes:
a calculating unit that calculates a representative value of the signal level of the acoustic data when the reset processing is performed;
a gain determining unit that determines a gain based on a representative value calculated by the calculating unit and a reference value of the signal level; and
a correcting unit that corrects the signal level of the acoustic data using the gain determined by the gain determining unit.

5. The acoustic control device according to claim 1, wherein the reset unit detects a silent interval between the acoustic data and performs the reset processing when receiving a switching notification signal indicating that the acoustic contents that are the playback target are switched.
